(19) United States
(12) Patent Application Publication
(10) Pub. No.: US 2009/0272881 A1
(43) Pub. Date: Nov. 5, 2009

(54) Apparatus, method, and system providing pixel having increased fill factor

(76) Inventors: Xiangli Li, San Jose, CA (US); Vijay Rajasekaran, San Jose, CA (US)

Correspondence Address: DICKSTEIN SHAPIRO LLP, 1825 EYE STREET NW, Washington, DC, 20006-5403, US

(21) Appl. No.: 12/149,607

(22) Filed: May 5, 2008

(51) Int. Cl. H01L 27/00; G01J 1/44; H04N 5/335

(52) U.S. Cl. 250/208.1; 250/214 R; 348/307

(57) ABSTRACT

A method, apparatus, and system providing a pixel having increased fill factor by removing the row select transistor. A reset transistor in the pixel is connected to a column line, and the column line is used alternatively as a pixel readout line and as a voltage supply line for resetting a storage region in the pixel through the resent transistor.

### FIELD OF THE INVENTION

Embodiments of the invention relate generally to the field of CMOS image sensors, and more specifically to a CMOS image sensor including a pixel architecture having an increased fill factor.

### BACKGROUND OF THE INVENTION

An imager, for example, a complementary metal oxide semiconductor (CMOS) imager, includes a focal plane array of pixels. Each pixel includes a photosensor, for example, a photogate, photoconductor or a photodiode overlying a substrate for producing a photo-generated charge in a doped region of the substrate. Conventionally, each CMOS pixel includes at least a source follower transistor and a row select transistor for coupling the source follower transistor to a column output line. The pixel also typically has a floating diffusion region connected to the gate of the source follower transistor. Charge generated by the photosensor is transferred to the floating diffusion region via a transfer transistor. The pixel often also includes a reset transistor for resetting the floating diffusion region to a predetermined charge level prior to charge transference.

FIG. 1 illustrates a block diagram of a CMOS imager 208 having a pixel array 200 with each pixel being constructed as described above. Pixel array 200 comprises a plurality of pixels arranged in a predetermined number of columns and rows. The pixels of each row in array 200 are all turned on at the same time by a row select line, and the pixels of each column are selectively output onto output lines by respective column select lines. A plurality of row and column select lines are provided for the entire array 200. The row lines are selectively activated in sequence by the row driver 210 in response to row address decoder 220 and the column select lines are selectively activated in sequence for each row activated by a column driver 260 incorporated in the column address decoder 270. Thus, a row and column address is provided for each pixel.

The CMOS imager 208 is operated by the control circuit 250, which controls address decoders 220, 270 for selecting the appropriate row and column lines for pixel readout, and row and column driver circuitry 210, 260, which apply driving voltage to the drive transistors of the selected row and column lines to carry out various tasks, including, for example, correlated double sampling readout.

In a correlated double sampling readout, the pixel output signals typically include a pixel reset signal, Vrst, sampled from the floating diffusion region when it is reset and a pixel image signal, Vsig, which is sampled from the floating diffusion region after charges generated by an image are transferred to it. The Vrst and Vsig signals are read by a sample and hold circuit 265 and are subtracted by a differential amplifier 267 that produces a signal Vrst-Vsig for each pixel, which represents the amount of light impinging on the pixel. This difference signal is digitized by an analog to digital converter 275. The digitized pixel signals are then fed to an image processor 280 to form and output a digital image. The digitizing and image processing can be performed on or off the chip containing the pixel array.

CMOS imagers of the type discussed above are generally known as discussed, for example, in U.S. Pat. No. 6,140,630, U.S. Pat. No. 6,376,868, U.S. Pat. No. 6,310,366, U.S. Pat. No. 6,326,652, U.S. Pat. No. 6,204,524, and U.S. Pat. No. 6,333,205, assigned to Micron Technology, Inc.

One of the challenges of designing pixels for use in CMOS imagers is achieving the best possible “fill factor” in the pixels. Fill factor is the percentage of the pixel area that is used by the photosensor for photon to charge conversion when capturing an image. The various transistors described above occupy space on the surface of the pixel and detracts from the amount of photosensitve area exposed to light. A pixel architecture and method of use having less transistors and a greater fill factor is desirable.

### BRIEF DESCRIPTION OF THE DRAWINGS

FIG. 1 shows a block diagram of a conventional CMOS imager.

FIG. 2 shows a schematic diagram of a conventional pixel.

FIG. 3 shows a schematic diagram of a pixel according to a first embodiment.

FIG. 4 shows a schematic diagram of FIG. 3 pixels connected to a column line of a pixel array with readout and control circuitry.

FIG. 5 shows an example readout and rolling shutter timing diagram for a pixel array having FIG. 4 columns lines and FIG. 3 pixels.

FIG. 6 shows an example camera processor system incorporating at least one imaging device constructed in accordance with an embodiment of the disclosure.

### DETAILED DESCRIPTION OF THE INVENTION

In the following detailed description, reference is made to the accompanying drawings, which form a part hereof and illustrate specific embodiments in which the invention may be practiced. In the drawings, like reference numerals describe substantially similar components throughout the several views. These embodiments are described in sufficient detail to enable those skilled in the art to practice the invention, and it is to be understood that other embodiments may be utilized, and that structural, logical and electrical changes may be made.

The terms “wafer” and “substrate” are to be understood as including silicon, silicon-on-insulator (SOI), or silicon-on-sapphire (SOS) technology, doped and undoped semiconductors, epitaxial layers of silicon supported by a base semiconductor foundation, and other semiconductor structures, as well as insulating substrates, such as quartz or glass. Furthermore, when reference is made to a “wafer” or “substrate” in the following description, previous process steps may have been utilized to form regions or junctions in the base semiconductor structure or foundation. In addition, the semiconductor need not be silicon-based, but could be based on silicon-germanium, germanium, or gallium-arsenide.

The term “pixel” refers to a picture element unit cell containing a photo-conversion device and other devices for converting electromagnetic radiation to an electrical signal. For purposes of illustration, a representative pixel is illustrated in the figures and description herein, and typically fabrication of all pixels in an image sensor will proceed simultaneously in a similar fashion.

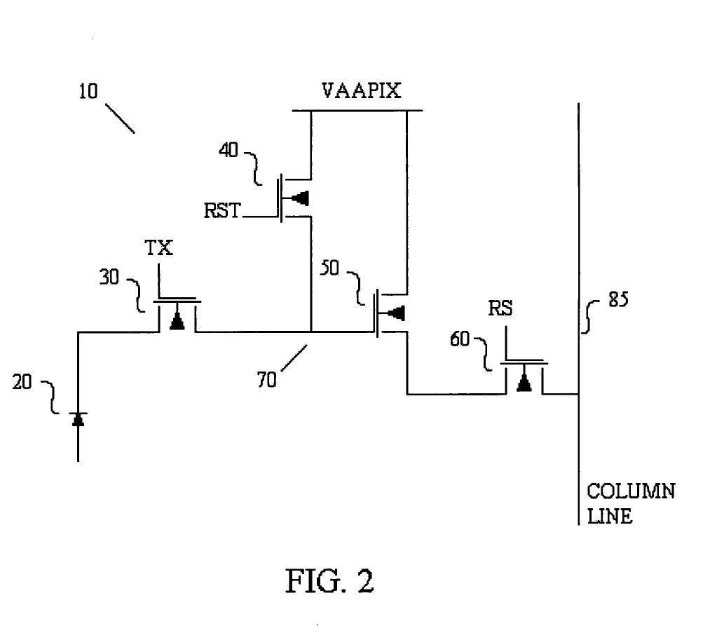

Referring now to the drawings, where like elements are designated by like reference numerals, FIG. 2 shows a conventional four-transistor CMOS pixel 10, including a photosensor 20, e.g., a pinned photodiode, a transfer transistor 30, a reset transistor 40, a source follower transistor 50, a row select transistor 60, a storage region 70, e.g., a floating diffusion, and an output column line 85. The photosensor 20 is connected to a source/drain terminal of the transfer transistor 30. The state of the transfer transistor 30 is controlled by a signal line TX. While the transfer transistor is in an “off” state, charge generated from light impinging upon the photosensor 20 accumulates within the photosensor 20. When the transfer transistor 30 is switched to an “on” state, the accumulated charge in the photosensor 20 is transferred to the storage region 70. The storage region 70 is connected to a gate of the source follower transistor 50. The source follower transistor 50 receives power from the VAAPIX line and amplifies the signal received from the storage region 70 for readout on column line 85. The pixel 10 is selected for readout by a row-select RS signal, which controls the row select transistor 60. When the row select transistor 60 is switched to an “on” state, the amplified signal from the source follower transistor 50 of a given row is transferred to the output column line Vout. The storage region 70 is also reset to a known voltage by the reset transistor 40 and a reset signal is also read out from the pixel for the correlated double sampling readout as previously described.

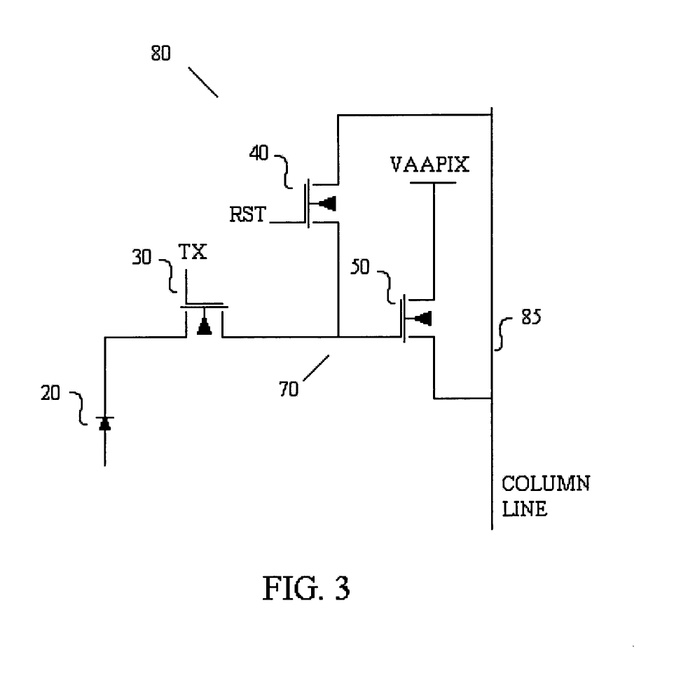

In order to improve the fill factor of a pixel embodiment described herein, the row select transistor 60 is removed, thereby providing additional surface area in the pixel for the photosensing element. With the row select transistor removed, alternative means for selecting and reading out a row of pixels are required in order for the pixel array to be compatible with conventional pixel readout techniques as described above. An embodiment of a pixel 80 having no row select pixel but capable of row-by-row pixel array readout is shown in FIG. 3.

Pixel 80 includes a photosensor 20, e.g., a pinned photodiode, a transfer transistor 30, reset transistor 40, a storage region 70, and a source follower transistor 50 connected to a pixel array column line 85. The photosensor 20 is connected to a source/drain terminal of the transfer transistor 30. The storage region 70 is connected to a gate of the source follower transistor 50. The source follower transistor 50 receives power from the VAAPIX line and amplifies the signal received from the storage region 70 for readout. Unlike the conventional pixel 10, in pixel 80 the source follower transistor 50 is connected via a source/drain directly to the column line 85. The storage region 70 may be reset to a known voltage by the reset transistor 40 for readout of a reset signal. The reset transistor 40 is not connected to VAAPIX as in the conventional pixel 10, but is instead connected to the column line 85.

The pixel 80 architecture allows for hard resetting of the storage region 70, i.e., operating the reset transistor 40 in full linear mode when resetting the storage region 70. The reset voltage applied to the storage region 70 is received from the column line 85, and is therefore separate from VAAPIX. By controlling the reset voltage and the voltage of signal RST applied to the gate of the reset transistor, the reset transistor 40 need not be operated in saturation mode, i.e., soft resetting. In a soft reset, an undesirable voltage drop occurs across the reset transistor, which may be avoided using the architecture of pixel 80. In addition, the advantage of eliminating the row select transistor not only improves the fill factor but also provides additional room for metal wiring.

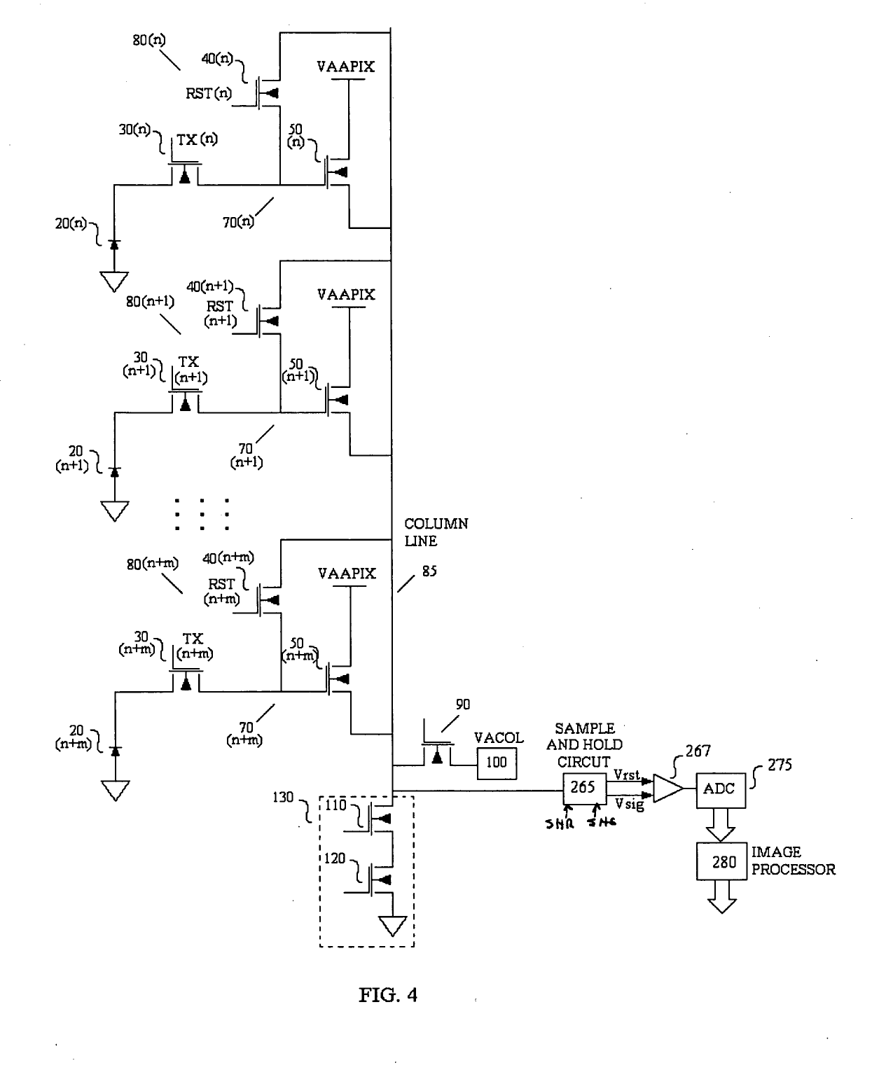

Turning now to readout circuitry, in one embodiment, shown in FIG. 4, to select a row for readout a switchtable voltage source VACOL 100 is switchably connected to the column line 85 by column control transistor 90. The column line 85 is used alternatively as either a readout line or a voltage supply line for providing a reset voltage from VACOL 100 to set the storage region 70 to either a reset voltage level or to a low voltage level sufficient to turn off the source follower 50 in a given row. Through control of the VACOL 100, column line 85 and the reset transistor 40, a conventional rolling shutter readout can be executed.

One example of a readout circuit which may be used is illustrated in FIG. 4 as comprising sample and hold circuit 265, differential amplifier 267, and analog-to-digital converter 275, as described above, which are connected to the column line 85. A bias circuit 130 comprising a line enable transistor 110 and a conventional bias transistor 120 are serially connected to the column line 85. The bias transistor 120 is maintained in a biased “on” state to permit a flow of current through the column line 85 when the enable transistor 110 is turned on.

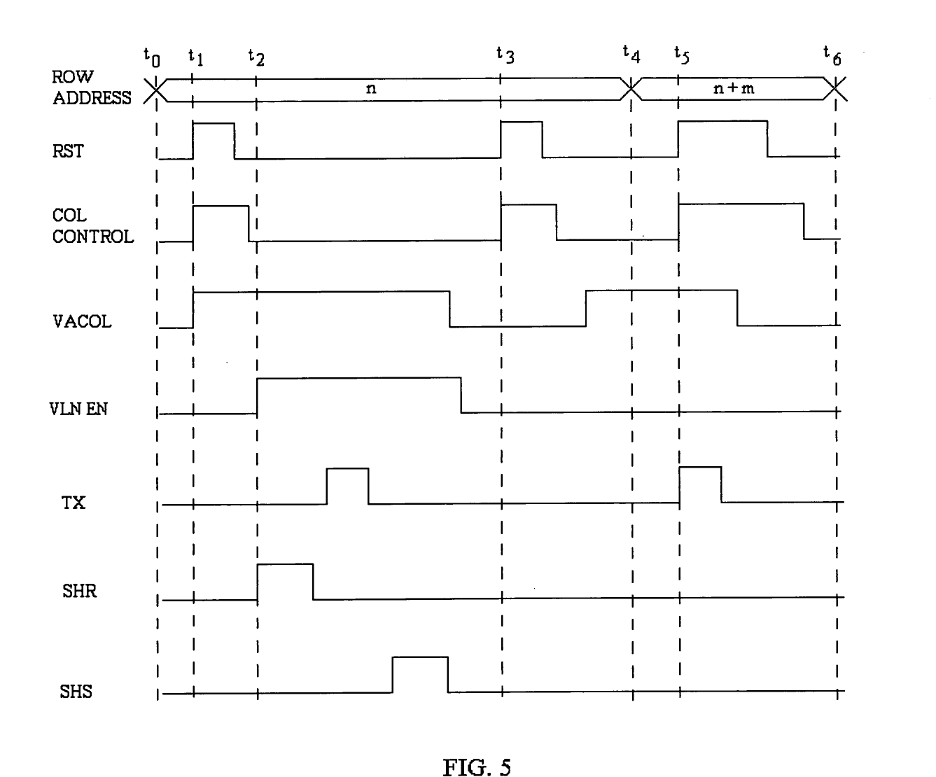

FIG. 5 shows a signal timing diagram of a readout of signal charge stored in photosensors 20 of pixels 80 in an nth pixel array row. The timing diagram is appropriate for a correlated double sampling rolling shutter readout of a pixel array having pixels 80 and column line 85 circuitry as described above.

The readout of row n begins at to and ends at t4. First, at ti the storage region 70(n) (FIG. 4) is reset by setting VACOL to a high level (e.g., 2.8V), pulsing a signal COL CONTROL to switch the column control transistor 90(n) to an “on” state, and pulsing a signal RST(n) to switch the reset transistor 40(n) to an “on” state. With column control transistor 90(n) in an “on” state, the high level VACOL voltage is applied to the column line 85, which is in turn applied to storage region 70(n) through the reset transistor 40(n), thus resetting storage region 70(n).

Next, the reset charge value and accumulated signal charge value are sampled at t₂-t₃. To sample the reset value, the COL CONTROL signal and RST(n) signal are dropped low to switch the column control transistor 90 and reset transistor 40(n) to an “off” state so that the column line 85 may be used as a readout line driven by VAAPIX. At t₂ a signal VLN EN is pulsed high to switch line enable transistor 110 to an “on” state, thereby connecting the column line 85 to the bias circuit 130. At this point VACOL may optionally remain high or be dropped low to conserve power. A sample-and-hold-reset signal SHR is pulsed at t₂ to sample the reset value stored by the storage region 70(n) into sample and hold circuit 265. After sampling the reset value, a signal TX(n) is pulsed to switch transfer transistor 30(n) to an “on” state, which causes a transfer of signal charge from the photosensor 20(n) to the storage region 70(n). A sample-and-hold-signal signal SHS is pulsed next to sample the signal value into sample and hold circuit 265.

After sampling the reset and signal values, the row n is unselected for any further readout by switching VACOL to a low voltage (if this has not yet been done, according to the option described above) and dropping the VLN EN signal low, switching the line enable transistor 110 to an “off” state. At t₃ the low VACOL voltage is applied to the source follower 50(n) by pulsing a signal RST(n) to switch the reset transistor 40(n) to an “on” state and pulsing a signal COL CONTROL to switch the column control transistor 90 to an “on” state, thereby switching the column line 85 back to a supply line state. The low VACOL voltage is applied to the storage region 70(n) through the reset transistor 40(n), and in turn applied to the gate of the source follower transistor 50(n), thereby switching the source follower transistor 50(n) to an “off” state and ending the readout of row n.

The rolling shutter of row n+m begins at t4 and ends at t₆. First, at t₄ VACOL is already set to a high voltage level. At t₅, the storage region 70 and photosensor 20 are reset by pulsing three signals: a signal RST(n+m) is pulsed to switch reset transistor 40(n+m) to an “on” state, a signal COL CONTROL is pulsed to switch column control transistor 90 to an “on” state, and a signal TX(n+m) is pulsed to switch transfer transistor 30(n+m) to an “on” state. The high VACOL voltage is thereby applied through the column line to both the storage region 70(n+m) and the photosensor 20(n+m), i.e., setting them both to the high VACOL voltage level. The applied high VACOL voltage will fully deplete the photosensor 20(n+m). If the photosensor 20(n+m) is a pinned photodiode, the applied VACOL voltage will return the photodiode to its pinned voltage. After the storage region 70(n+m) and photosensor 20(n+m) have been reset, signal TX(n+m) is dropped low to switch the transfer transistor 30(n+m) to an “off” state and begin the integration period for pixels 80(n+m) in row (n+m). At the start of the integration period, VACOL is dropped to a low voltage level while the reset transistor 40(n+m) and column control transistor 90 remain in an “on” state. The low VACOL voltage is thereby applied to storage region 70(n+m), and in turn to the source follower 50(n+m), switching it to an “off” state for the duration of the integration period. The integration period will continue until the readout of pixels in row (n+m), which is executed as described above with reference to row (n).

Although an embodiment has been described in connection with a four-transistor pixel, the column circuit for selectively applying operating power to a pixel or permitting pixel readout over a same column line may also be applied to pixels having a different number of select transistors and operating circuits. In addition, although embodiments have been described using non-shared pixel architecture, the embodiments may be used in any shared pixel architecture, e.g., 2-way shared, 3-way shared, vertical 4-way shared, or 2×2×4-way shared architectures, etc.

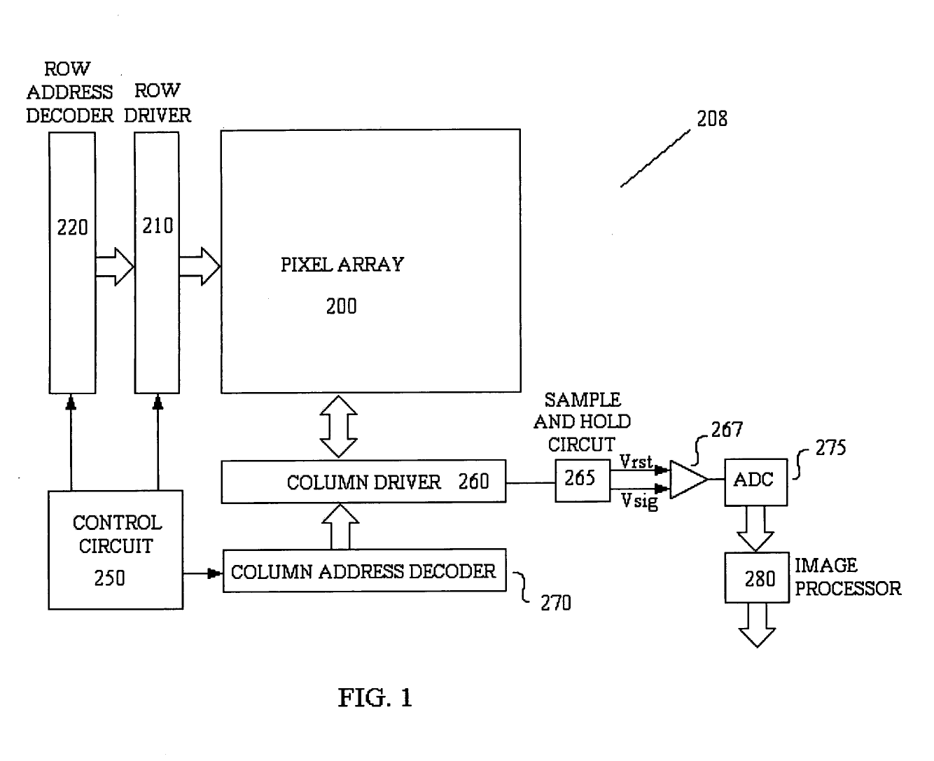

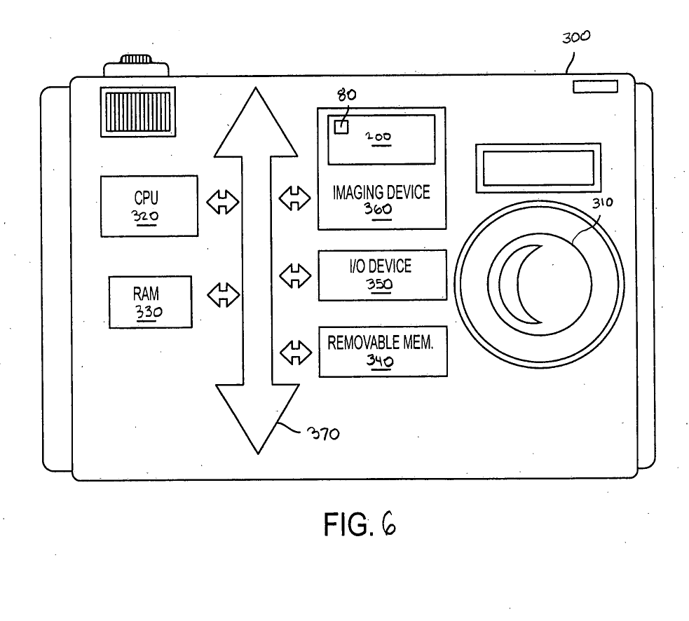

FIG. 6 is a block diagram of a processing system, for example, a camera system 300 having a lens 310 for focusing an image on imaging device 360 when a shutter release button 315 is pressed. Imaging device 360 may be configured as shown in FIG. 1, but including a pixel array 200 constructed incorporating pixels 80 in accordance with an embodiment of the present invention. Although illustrated as a camera system the system 300 may also be a computer system, a process control system, or any other system employing a processor and associated memory. The system 300 includes a central processing unit (CPU) 320, e.g., a microprocessor, that communicates with the imaging device 360 and one or more I/O devices 350 over a bus 370. It must be noted that the bus 370 may be a series of buses and bridges commonly used in a processor system, but for convenience purposes only, the bus 370 has been illustrated as a single bus. The processor system 300 may also include random access memory (RAM) device 330 and some form of removable memory 340, such a flash memory card, or other removable memory as is well known in the art.

While embodiments have been described in detail, it should be readily understood that they are not limited to the disclosed embodiments. Rather the embodiments can be modified to incorporate any number of variations, alterations, substitutions or equivalent arrangements not heretofore described

What is claimed as new and desired to be protected by Letters Patent of the United States is:

1. A pixel circuit, comprising:
a photosensor that generates and accumulates charge from incoming light;
a storage region that stores charge;
a reset transistor that resets the storage region, having a source/drain connected to the storage region and a source/drain connected to a column line;
a transfer transistor that controls a transfer of charge between the photosensor and the storage region, having a source/drain connected to the storage region, and a source/drain connected to the photosensor; and
a pixel output transistor having a gate connected to the storage region, a source/drain connected to the column line, and a source/drain connected to an operating voltage supply line.

2. The pixel circuit of claim 1, further comprising a line enable transistor that switchably connects the column line to a bias circuit to switch the column line to a pixel signal readout line.

3. The pixel circuit of claim 1, further comprising a control transistor having a source/drain connected to the column line and a source/drain connected to a control voltage source for selectively connecting the control voltage source to the column line to switch the column line to a voltage supply line.

4. The pixel circuit of claim 3, wherein the control voltage source selectively provides a first voltage and a second voltage.

5. An imaging device, comprising:
a pixel array, comprising pixels arranged in rows and columns, wherein a plurality of pixels arranged in a given column are connected to a common column line, each of the plurality of pixels being capable of supplying an output signal to the column line and including a first transistor that selectively connects the column line to a storage region to reset the storage region; and
circuitry for switchably operating the column line in a first mode to supply a supply voltage to the column line or in a second mode for receiving an output signal from a pixel.

6. The imaging device of claim 5, further comprising readout circuitry connected to the column line.

7. The imaging device of claim 5, wherein the circuitry for switchably operating the column line comprises:
a second transistor connected to at least one column line for controlling application of a supply voltage to the column line to operate the column line as an operating power supply line; and
a bias circuit connected to the column line to operate the column line as a pixel signal readout line.

8. The imaging device of claim 7, wherein the bias circuit comprises a third transistor and a fourth transistor connected in series between the column line and a ground potential.

9. The imaging device of claim 7, wherein the supply voltage comprises a switchable voltage supply source which in one mode provides an operating power voltage level and in another mode provides a low voltage level sufficient to prevent a pixel from outputting a signal to the column line.

10. A method of operating a pixel, comprising:
selectively coupling a first voltage to a column line;
resetting a storage region in the pixel to the first voltage via the column line;
uncoupling the first voltage from the column line and enabling the column line to receive a pixel output signal;
providing a pixel output signal on the column line representing a reset level at the storage region;
transferring a signal charge from a photosensor in the pixel to the storage region; and
providing a pixel output signal on the column line representing the transferred charge level at the storage region.

11. The method of claim 10, further comprising sampling the pixel output signal on the column line representing the read level and transferred charge level.

12. The method of claim 10, further comprising
applying a second voltage to the column line; and
setting the storage region to the second voltage via the column line,
the second voltage being at a level to prevent an output signal from being generated by the pixel.

13. The method of claim 10, wherein the step of applying the first voltage to the column line comprises:
raising a column control voltage to a first voltage; and
pulsing a signal to a control transistor to apply the control voltage to the column line.

14. The method of claim 13, wherein the step of resetting the storage region in the pixel comprises pulsing a signal to a reset transistor in the pixel to connect the storage region to the column line during a time that the final voltage is applied to the column line.

15. The method of claim 12, wherein the step of setting the storage region to the second voltage comprises pulsing a signal to a reset transistor in the pixel to switch the reset transistor to an on state, thereby connecting the storage region to the column line during a time that the second voltage is applied to the column line.

16. The method of claim 10, wherein the second voltage level lowers the storage region to a level which switches a source follower transistor connected to the storage region to an off state.

17. A method of operating a pixel connected to a column line, comprising:
setting a voltage source to a first voltage level;
applying a signal to a control transistor connected between the voltage source and the column line to switch the control transistor to an on state and apply the first voltage level to the column line;
applying a signal to a first transistor in a pixel connected between the column line and a storage region in the pixel to switch the first transistor to an on state and reset the storage region to the first voltage;
removing the signal applied to the first transistor to switch off the first transistor;
removing the signal applied to the control transistor to switch off the control transistor;
applying a signal to a second transistor to switch the second transistor to an on state and connect a bias circuit to the column line, enabling a readout of signal charge at the storage region through a third transistor of the pixel connected to the column line;
applying a signal to a sample and hold circuit to sample a reset level charge at the storage region;
pulsing a signal to a fourth transistor in the pixel to transfer a signal charge from a photosensor to the storage region in the pixel;
applying a signal to the sample and hold circuit to sample the transferred signal charge at the storage region.

18. The method of claim 17, further comprising:
setting the voltage source to a second voltage level, where the second voltage level when applied to the third transistor operates to switch the third transistor to an off state;
removing the signal applied to the second transistor to switch the second transistor to an off state;
applying a signal to the control transistor to apply the second voltage level to the column line; and
applying a signal to the first transistor to set the storage region to the second voltage.

19. The method of claim 18, further comprising resetting the pixel by:
setting the voltage source to the first voltage level;
applying a signal to the first transistor to switch the first transistor to an on state;
applying a signal to the control transistor to switch the control transistor to an on state; and
applying a signal to the fourth transistor to switch the fourth transistor to an on state and reset the photosensor.

20. The method of claim 19 further comprising initiating an integration period in the pixel by:
removing the signal applied to the fourth transistor to switch the fourth transistor to an off state after the photosensor is reset.

21. A camera system, comprising
a lens;
a pixel array for receiving an image from the lens and comprising a plurality of pixels, the pixels comprising:
a photosensor for accumulating and generating photo generated charge;
a storage region;
a transfer transistor coupled between the photosensor and the storage region for transferring charge between the photosensor and the storage region;
a reset transistor coupled between the storage region and a column line for controlling a transfer of charge between the column line and the storage region; and,
a source follower transistor that provides an output signal to the column line based on charge stored at the storage region.

22. The camera system of claim 21, wherein the pixel array further comprises:
a bias circuit connected to the column line; and
a column voltage source switchably connected to the column line;
wherein the bias circuit and column voltage source alternatively operate the column line as a pixel signal readout line or an operating voltage supply line for the pixel.

23. The camera system of claim 21, wherein the pixel array further comprises a column voltage source providing a first voltage source to the column line for a resetting operation and a second voltage source to the column line to prevent the pixel from providing an output signal to the column line.
